(19) United States
(12) Patent Application Publication
(10) Pub. No.: US 2025/0201607 A1
(43) Pub. Date: Jun. 19, 2025

(54) PACKAGE SHUTTLE FOR ENHANCED PACKAGE HANDLING RELIABILITY AND METHODS FOR FORMING THE SAME

(71) Applicant: Taiwan Semiconductor Manufacturing Company Limited, Hsinchu (TW)

(72) Inventors: Shin-Han You, Taoyuan City (TW); Ting-Yu Chiu, Hsinchu (TW); Yi-Neng Chang, Hsinchu (TW); Chien Fang Huang, Hsinchu (TW)

(21) Appl. No.: 18/402,059

(22) Filed: Jan. 2, 2024

Related U.S. Application Data
(60) Provisional application No. 63/611,218, filed on Dec. 18, 2023.

(51) Int. Cl. H01L 21/673; H01L 21/683

(52) U.S. Cl. CPC H01L 21/673; H01L 21/6838

(57) ABSTRACT

A package shuttle includes a lower shuttle assembly including a first lower shuttle structural element, an array of conductive plates located over the first lower shuttle structural element, and at least one second lower shuttle structural element including an array of shuttle openings therethrough. The array of shuttle openings overlies the array of conductive plates and is configured to accommodate an array of semiconductor packages therein. The package shuttle may further include an upper shuttle assembly including an carrier substrate and an array of package clamps attached to a bottom surface of the carrier substrate. The array of package clamps is configured to mate with the lower shuttle assembly such that the lower shuttle assembly is secure against lateral movement relative to the upper shuttle assembly upon mating of the lower shuttle assembly with the upper shuttle assembly.

### RELATED APPLICATIONS

This application claims the benefit of priority from U.S. Provisional Application Ser. No. 63/611,218, entitled “Package Shuttle For Enhanced Package Handling Reliability And Methods For Forming The Same,” filed on Dec. 18, 2023, the entire contents of which is incorporated herein by reference for all purposes.

### BACKGROUND

Semiconductor packages contain integrated circuits or chips, and are prone to damage during transport due to mechanical shocks. A package shuttle that is configured to transport semiconductor packages may undergo thermal expansion at elevated temperatures, which may cause undesirable contact between edges of the semiconductor packages and the package shuttle. This undesirable contact may result in misalignment, collision, or dropping of some of the semiconductor packages. A secure package shuttle that may provide reliable transport of semiconductor packages is desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of an intermediate first embodiment structure after disposing a first lower shuttle structural element, an array of thermal interface material plates, and an array of conductive plates over a heater element according to an embodiment of the present disclosure.

FIG. 1B is a top-down view of the intermediate first embodiment structure along the vertical plane A-A′ of FIG. 1A.

FIG. 2A is a vertical cross-sectional view of the intermediate first embodiment structure after formation of a lower shuttle assembly according to an embodiment of the present disclosure.

FIG. 2B is a top-down view of the intermediate first embodiment structure along the vertical plane A-A′ of FIG. 2A.

FIG. 3A is a vertical cross-sectional view of the intermediate first embodiment structure after disposing an array of semiconductor packages within an array of shuttle openings according to an embodiment of the present disclosure.

FIG. 3B is a top-down view of the intermediate first embodiment structure along the vertical plane A-A′ of FIG. 3A.

FIG. 4 is a vertical cross-sectional view of the intermediate first embodiment structure after positioning an upper shuttle assembly over the lower shuttle assembly according to an embodiment of the present disclosure.

FIG. 5 is a vertical cross-sectional view of the intermediate first embodiment structure after securing the array of semiconductor packages by disposing the upper shuttle assembly on the lower shuttle assembly according to an embodiment of the present disclosure.

FIG. 6 is a vertical cross-sectional view of the first embodiment structure after lifting the array of semiconductor packages using the upper shuttle assembly according to an embodiment of the present disclosure.

FIG. 7A is a vertical cross-sectional view of an intermediate second embodiment structure after disposing a second lower shuttle structural element, an array of thermal interface material plates, and an array of conductive plates over a heater element according to an embodiment of the present disclosure.

FIG. 7B is a top-down view of the intermediate second embodiment structure along the vertical plane A-A′ of FIG. 7A.

FIG. 8A is a vertical cross-sectional view of the intermediate second embodiment structure after formation of a lower shuttle assembly according to an embodiment of the present disclosure.

FIG. 8B is a top-down view of the intermediate second embodiment structure along the vertical plane A-A′ of FIG. 8A.

FIG. 9A is a vertical cross-sectional view of the intermediate second embodiment structure after disposing an array of semiconductor packages within an array of shuttle openings according to an embodiment of the present disclosure.

FIG. 9B is a top-down view of the intermediate second embodiment structure along the vertical plane A-A′ of FIG. 9A.

FIG. 10 is a vertical cross-sectional view of the intermediate second embodiment structure after positioning an upper shuttle assembly over the lower shuttle assembly according to an embodiment of the present disclosure.

FIG. 11 is a vertical cross-sectional view of the intermediate second embodiment structure after securing the array of semiconductor packages by disposing the upper shuttle assembly on the lower shuttle assembly according to an embodiment of the present disclosure.

FIG. 12 is a vertical cross-sectional view of the second embodiment structure after lifting the array of semiconductor packages using the upper shuttle assembly according to an embodiment of the present disclosure.

FIG. 13A is a vertical cross-sectional view of an intermediate third embodiment structure after disposing a third lower shuttle structural element, an array of thermal interface material plates, and an array of conductive plates over a heater element according to an embodiment of the present disclosure.

FIG. 13B is a top-down view of the intermediate third embodiment structure along the vertical plane A-A′ of FIG. 13A.

FIG. 14A is a vertical cross-sectional view of the intermediate third embodiment structure after formation of a lower shuttle assembly according to an embodiment of the present disclosure.

FIG. 14B is a top-down view of the intermediate third embodiment structure along the vertical plane A-A′ of FIG. 14A.

FIG. 15A is a vertical cross-sectional view of the intermediate third embodiment structure after disposing an array of semiconductor packages within an array of shuttle openings according to an embodiment of the present disclosure.

FIG. 15B is a top-down view of the intermediate third embodiment structure along the vertical plane A-A′ of FIG. 15A.

FIG. 16 is a vertical cross-sectional view of the intermediate third embodiment structure after positioning an upper shuttle assembly over the lower shuttle assembly according to an embodiment of the present disclosure.

FIG. 17 is a vertical cross-sectional view of the intermediate third embodiment structure after securing the array of semiconductor packages by disposing the upper shuttle assembly on the lower shuttle assembly according to an embodiment of the present disclosure.

FIG. 18 is a vertical cross-sectional view of the third embodiment structure after lifting the array of semiconductor packages using the upper shuttle assembly according to an embodiment of the present disclosure.

FIG. 19 is a flowchart that illustrates general processing steps for manufacturing a device structure according to the various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Elements with the same reference numerals refer to the same element, and are presumed to have the same material composition and the same thickness range unless expressly indicated otherwise.

Various embodiments of the present disclosure are directed to a package shuttle, semiconductor structures using the same, and methods of operating the same to transport semiconductor packages. Semiconductor packages may contain integrated circuits or chips, which are delicate components that need to be securely held and transported during various stages of manufacturing and testing. A package shuttle including an array of package clamps may be used to transport an array of semiconductor packages in a protected environment. A package shuttle may be alternatively referred to as a package carrier or as a package handler. According to an aspect of the present disclosure, a package shuttle is provided in which semiconductor packages are thermally coupled to a heater element while portions of the package shuttle that laterally surround the semiconductor packages may have less thermal coupling to the heater element. In this manner, the semiconductor packages loaded into the package shuttle may be heated to an elevated temperature during transport without causing thermal-expansion-induced mechanical damages to the semiconductor packages. The various embodiments of the present disclosure are now described with reference to accompanying drawings.

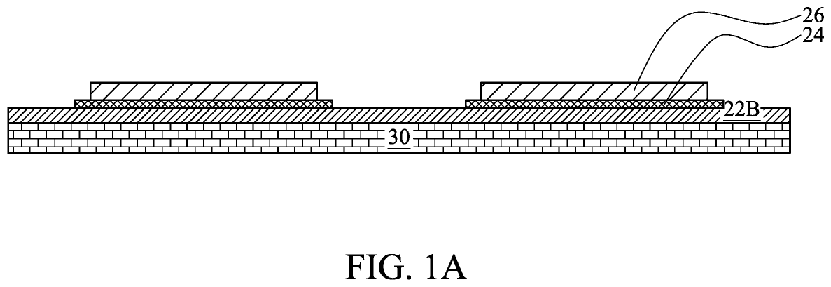

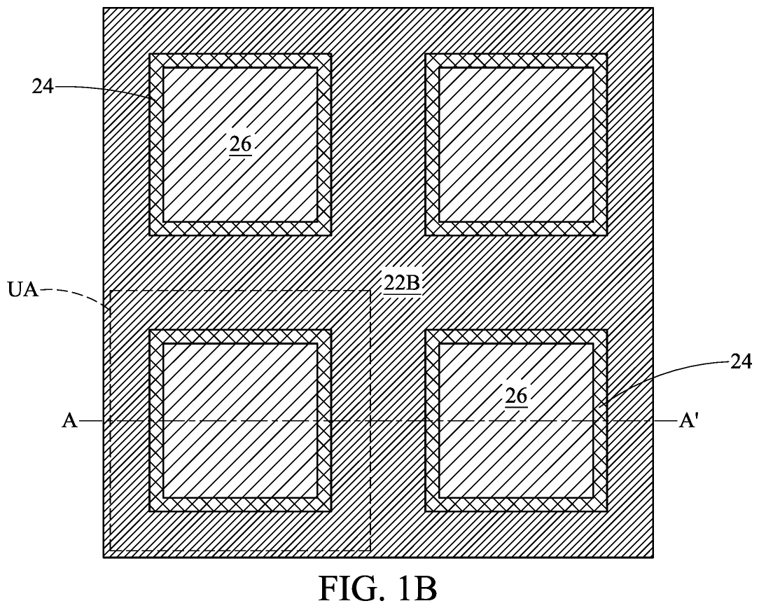

Referring to FIGS. 1A and 1B, an intermediate first embodiment structure according to an embodiment of the present disclosure is illustrated. The first embodiment structure comprises a first lower shuttle structural element 22B that is located on a heater element 30. The first lower shuttle structural element 22B is a structural element that is used to form a lower shuttle assembly, which is incorporated into a package shuttle for transporting a plurality of semiconductor packages.

In one embodiment, the first lower shuttle structural element 22B is a structural element having a configuration of an unperforated plate having a uniform thickness throughout and without any opening therethrough. In this configuration, the first lower shuttle structural element 22B is referred to as a bottom shuttle plate 22B. The thickness of the bottom shuttle plate 22B may be in a range from 1 mm to 3 mm, although lesser and greater thicknesses may also be used. In one embodiment, the bottom shuttle plate 22B may comprise a metal or a semiconductor material having a coefficient of thermal expansion that is less than 1.22×10⁻⁵/K at 20 degrees Celsius, and/or is preferably less than 1.0×10⁻⁵/K at 20 degrees Celsius. For example, the bottom shuttle plate 22B may comprise a metallic material such as W, Fe, Mo, Ti, Ta, and alloys thereof; or a metallic nitride material such as WN, TiN, TaN, MoN, and alloys thereof; or a semiconductor material such as polysilicon or a single crystalline silicon.

The heater element 30 may comprise any type of heater element that is configured to provide heat to the bottom shuttle plate 22B. For example, the heater element 30 may comprise an embedded resistive heater with a temperature control mechanism that is configured to control the temperature of the heater element 30 at a predetermined target temperature, which may be any temperature greater than room temperature (i.e., 20 degrees Celsius). A programmable temperature controller (not shown) and a power supply chord (not shown) may be attached to the heater element 30 so that power is supplied to the heater element 30 during transfer of the package shuttle to be subsequently formed.

Generally, the semiconductor shuttle may be configured to transport an array of semiconductor packages such as an M×N rectangular array of semiconductor packages. M may be a number in a range from 2 to 100, and N may be a number in a range from 2 to 100, although greater numbers may also be used for each of M and N. The illustrated region shown in FIGS. 1A and 1B corresponds to a region of the first embodiment structure for transporting a 2×2 array of semiconductor packages. As such, the illustrated region may be less than the entirety of the first embodiment structure. Generally, a unit area UA of repetition may be repeated in two different horizontal directions to provide a package shuttle that may transport an array of semiconductor packages. Further, while a rectangular array is illustrated in the present disclosure, a non-rectangular periodic array such as a hexagonal array or a non-periodic array may also be used. As such, the present disclosure is not limited by any particular type of array configurations.

An array of thermal interface material plates 24 may be formed on the top surface of the bottom shuttle plate 22B. The thermal interface material plates 24 comprise a thermal interface material, which is a material that improves the thermal coupling between two surfaces by filling gaps and enhancing heat transfer therebetween. The thermal interface material may comprise a thermal grease, a thermal pad, a thermal paste, a metal-based thermal interface material, etc. The thermal conductivity of the thermal interface material of the thermal interface material plates 24 may be greater than 0.026 W/m·K, and/or may be preferably greater than 0.1 W/m·K, and/or may be even more preferably greater than 1 W/m·K. The thickness of the thermal interface material plates 24 may be in a range from 100 microns to 500 microns, although lesser and greater thicknesses may also be used. A thermally conductive material may be applied and patterned over the top surface of the bottom shuttle plate 22B to form the array of thermal interface material plates 24.

The array of thermal interface material plates 24 may be arranged in the pattern of the array of shuttle openings 27 to be subsequently used to contain an array of semiconductor packages. Each thermal interface material plate 24 is formed within a respective unit area UA. The array of thermal interface material plates 24 may be formed as a two-dimensional periodic array such as a rectangular array. Each thermal interface material plate 24 may have a greater area than the area of a respective shuttle opening to be subsequently formed thereabove. Thus, each thermal interface material plate 24 has a greater area than the area of a semiconductor package to be subsequently positioned thereupon. In a non-limiting illustrative example, each thermal interface material plate 24 may have a length greater than 31 mm, and/or 40 mm, and/or 50 mm, and/or 60 mm; and may have a width greater than 31 mm, and/or 40 mm, and/or 50 mm, and/or 60 mm.

An array of conductive plates 26 may be formed over the array of thermal interface material plates 24, for example, by directly attaching the array of conductive plates 26 to the array of thermal interface material plates 24, or by depositing and patterning a thermally conductive material. The array of conductive plates 26 may comprise a metallic material providing thermal conductivity greater than 70 W/m·K. In one embodiment, the array of conductive plates 26 comprises a metallic material having a thermal conductivity that is higher than a thermal conductivity of a material of the array of thermal interface material plates 24 at least by a factor of 10.

In an illustrative example, the array of conductive plates 26 may comprise, and/or may consist essentially of, a metal such as silver, copper, gold, aluminum, tungsten, nickel, iron, platinum, etc. Other suitable conductive materials are within the contemplated scope of disclosure. The thickness of the conductive plates 26 may be in a range from 0.5 mm to 3 mm, although lesser and greater thicknesses may also be used. The size of the conductive plate 26 is smaller than the size of a respective underlying thermal interface material plate 24. In one embodiment, each of a conductive plate 26 may be laterally offset inward from a most proximal periphery of a respective underlying thermal interface material plate 24 by a lateral offset distance in a range from 25 microns to 500 microns, such as from 50 microns to 300 microns.

Generally, a heater element 30 may be attached to a bottom surface of the first lower shuttle structural element (such as the bottom shuttle plate 22B). In one embodiment, the first lower shuttle structural element may comprise an unperforated plate (such as a bottom shuttle plate 22B) having a planar top surface located under a horizontal plane including bottom surfaces of the array of conductive plates 26. An array of thermal interface material plates 24 may be in contact with the first lower shuttle structural element (such as the bottom shuttle plate 22B). Each thermal interface material plate 24 within the array of thermal interface material plates 24 is in contact with a bottom surface of a respective conductive plate 26 within the array of conductive plates 26.

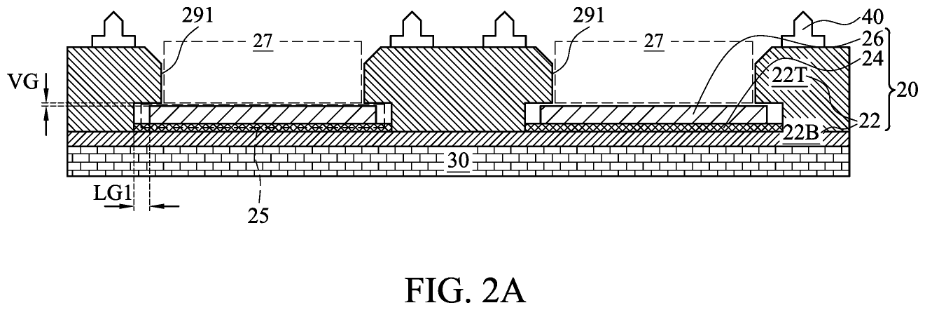

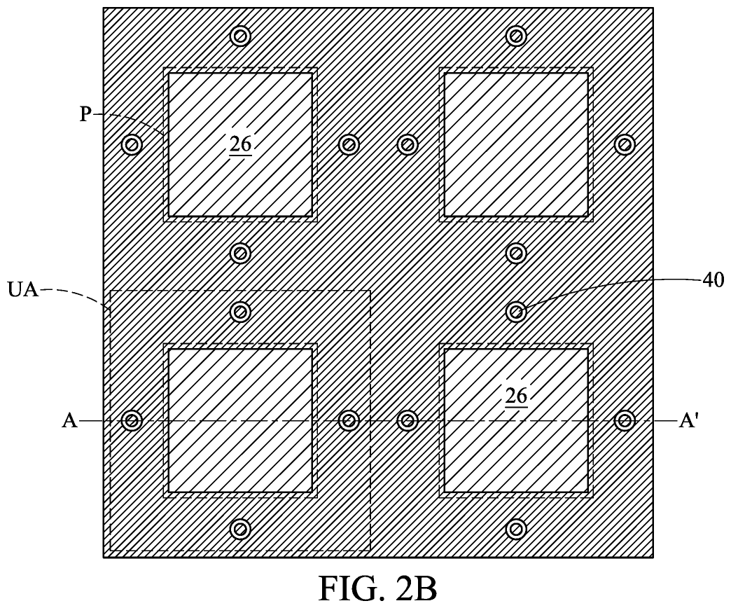

Referring to FIGS. 2A and 2B, a second lower shuttle structural element including an array of shuttle openings 27 therethrough is provided. In one embodiment, the second lower shuttle structural element may comprise a perforated plate, which is herein referred to as a top shuttle plate 22T. The top shuttle plate 22T comprises an array of stepped openings therethrough. As used herein, a “stepped opening” refers to an opening having a stepped sidewall in a vertical cross-sectional profile, i.e., a sidewall having at least two vertically-extending surface segments and at least one horizontally-extending surface segment connecting a respective pair of vertically-extending surface segments. The stepped openings through the top shuttle plate 22T may define multiple sets of openings located at different levels and having partial areal overlaps in a plan view (such as a top-down view or a bottom-up view). As used herein, a “plan view” refers to a view along a vertical direction in which profiles of all elements are illustrated irrespective of visibility along the view direction.

Specifically, each stepped opening through the top shuttle plate 22T may comprise a shuttle opening 27 that is provided in an upper portion of the stepped opening, and a cavity 25 that is provided underneath the shuttle opening 27 and having a greater area than the area of the shuttle opening 27. The area of the cavity 25 may include the entirety of the area of the shuttle opening 27 within any stepped opening. The size of the shuttle opening 27 is selected to be greater than the size of a semiconductor package to be subsequently placed therein. In one embodiment, the size of each cavity 25 may be selected to match the size of a thermal interface material plate 24.

The second lower shuttle structural element (comprising the top shuttle plate 22T) may be configured to mate with the top surface of the first lower shuttle structural element (comprising the bottom shuttle plate 22B) by contacting a grid-shaped physically-exposed surface segment of the top surface of the first lower shuttle structural element that is not covered by the array of thermal interface material plates 24. For example, the top shuttle plate 22T may be attached to the bottom shuttle plate 22B by using a combination of through-holes (not illustrated) that extend through the top shuttle plate 22T and the bottom shuttle plate 22B and fixture elements (such as bolts, nuts, screws, clips, etc.) that pass through the through-holes. Alternatively or additionally, an adhesive layer (not shown) may be used between the top shuttle plate 22T and the bottom shuttle plate 22B to bond the top shuttle plate 22T and the bottom shuttle plate 22B. The combination of the first lower shuttle structural element (which may be comprise the bottom shuttle plate 22B) and the second lower shuttle structural element (which may be comprise the top shuttle plate 22T) constitutes a shuttle plate assembly 22.

Upon assembly of the top shuttle plate 22T with the bottom shuttle plate 22B, a lower shuttle assembly 20 is formed. The lower shuttle assembly 20 comprises a first lower shuttle structural element (which may comprise a bottom shuttle plate 22B), an array of thermal interface material plates 24 located over the first lower shuttle structural element, an array of conductive plates 26 located over the array of thermal interface material plates 24, and a second lower shuttle structural element (comprising a top shuttle plate 22T) including an array of shuttle openings 27 therethrough. The array of shuttle openings 27 overlies the array of conductive plates 26, and is configured to accommodate an array of semiconductor packages therein.

In one embodiment, the bottom shuttle plate 22B has a planar top surface located under a horizontal plane including bottom surfaces of the array of conductive plates 26. In one embodiment, the lower shuttle assembly 20 comprises an array of cavities 25 underneath the array of shuttle openings 27 such that each cavity 25 selected from the array of cavities 25 underlies, and has a greater lateral extent than, a respective shuttle opening 27 selected from the array of shuttle openings 27. In one embodiment, each shuttle opening 27 within the array of shuttle openings 27 is located inside an area of a periphery of a respective one of the conductive plates 26 in a plan view.

Generally, each conductive plate 26 within the array of conductive plates 26 is laterally spaced from a combination of the first lower shuttle structural element and the second lower shuttle structural element (such as a combination of the bottom shuttle plate 22B and the top shuttle plate 22T) by a lateral gap (such as a first lateral gap LG1). According to an aspect of the present disclosure, the first lateral gap LG1 is designed to be at a positive value at the highest operating temperature of the lower shuttle assembly 20. In other words, even in embodiments in which the various components of the lower shuttle assembly 20 thermally expand to their respective maximum volume at the highest operating temperature of the lower shuttle assembly 20, the value for the first lateral gap LG1 remains positive, and the conductive plates 26 do not make physical contact with the combination of the bottom shuttle plate 22B and the top shuttle plate 22T.

Generally, the thermal expansion of each structural element may be estimated using a linear thermal expansion model, and is given by the formula of ΔL=L₀×α×ΔT, in which ΔL refers to the change in a lateral dimension, L₀ is the lateral dimension of a structural element, α is the coefficient of thermal expansion of the structural element, and ΔT is the change in temperature from the room temperature (at which the value of L is measured). In an illustrative example, the lateral dimensions of each shuttle opening 27 may be in a range from 30 mm to 100 mm, and the first lateral gap LG1 may be in a range from 25 microns to 500 microns, such as from 50 microns to 300 microns, although lesser and greater values may also be used for the first lateral gap LG1 (as measured at room temperature, i.e., at 20 degrees Celsius).

The material of the second lower shuttle structural element (such as the top shuttle plate 22T) may be the same as, or may be different from, the material of the first lower shuttle structural element (such as the bottom shuttle plate 22B). For example, the top shuttle plate 22T may comprise a metallic material such as W, Fe, Mo, Ti, Ta, and alloys thereof; or a metallic nitride material such as WN, TiN, TaN, MoN, and alloys thereof; or a semiconductor material such as polysilicon or a single crystalline silicon. The thermal expansion coefficient of the top shuttle plate 22T is generally less than 2.0×10⁻⁵/K at 20 degrees Celsius. Generally, the first lower shuttle structural element and the second lower shuttle structural element may have a respective thermal conductivity that is less than a thermal conductivity of the array of conductive plates 26.

In one embodiment, the array of shuttle openings 27 comprises an array of first sidewalls 291 of the second lower shuttle structural element (such as the top shuttle plate 22T). In one embodiment, each first sidewall 291 may have a tapered upper sidewall segment and a vertical lower sidewall segment. The bottom peripheries of the first sidewalls 291 of the second lower shuttle structural element may be located above a horizontal plane including top surfaces of the array of conductive plates 26. In one embodiment, each conductive plate 26 within the array of conductive plates 26 is vertically spaced from a respective overhanging portion of the at least one second lower shuttle structural element (such as the top shuttle plate 22T) by a vertical gap VG. The vertical gap VG may be in a range from 10 microns to 300 microns, such as from 20 microns to 200 microns, although lesser and greater values may also be used for the vertical gap VG (as measured at room temperature).

In one embodiment, in a plan view of a stepped opening (25, 27), the periphery of the cavity 25 may be laterally offset outward relative to the periphery of the shuttle opening 27 by a lateral offset distance which is greater than the first lateral gap LG1. Thus, each conductive plate 26 may comprise a respective peripheral region having an areal overlap with a respective overhanging portion of the second lower shuttle structural element (such as the top shuttle plate 22T) in a plan view. In one embodiment, the top shuttle plate 22T includes stepped openings therethrough. Each of the stepped openings comprises a respective shuttle opening 27 within the array of shuttle openings 27 and further comprises a respective plate-level opening (such as a cavity 25) within an array of plate-level openings (such as the array of cavities 25). The respective plate-level opening (such as a cavity 25) has a greater area than the respective shuttle opening 27.

According to an aspect of the present disclosure, a top surface of the second lower shuttle structural element (such as the top shuttle plate 22T) may comprise an array of topographical features that may be used to induce self-alignment during mating of the lower shuttle assembly 20 with an upper shuttle assembly to be subsequently used. The topographical features may comprise an array of protrusions 40 or an array of cavities configured to receive a mating array of protrusions. In the illustrated example, the topographical features on the top surface of the top shuttle plate 22T comprise an array of protrusions 40. In one embodiment, the array of protrusions 40 may be arranged as a periodic array of protrusions 40 having the same periodicity as the array of shuttle openings 27. The array of topographical features may comprise geometrical features that are conductive to self-alignment between the top shuttle plate 22T and upper shuttle assembly to be subsequently used. In embodiments in which an array of protrusions 40 is used, the protrusions 40 may comprise a conical tip that may be advantageously used to induce lateral sliding between the top shuttle plate 22T and the upper shuttle assembly during a subsequent alignment process.

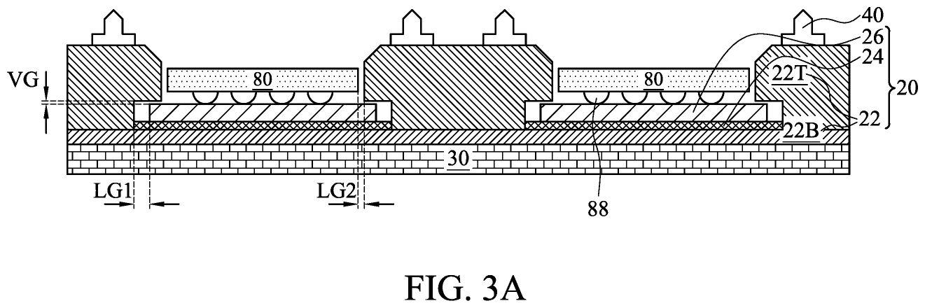

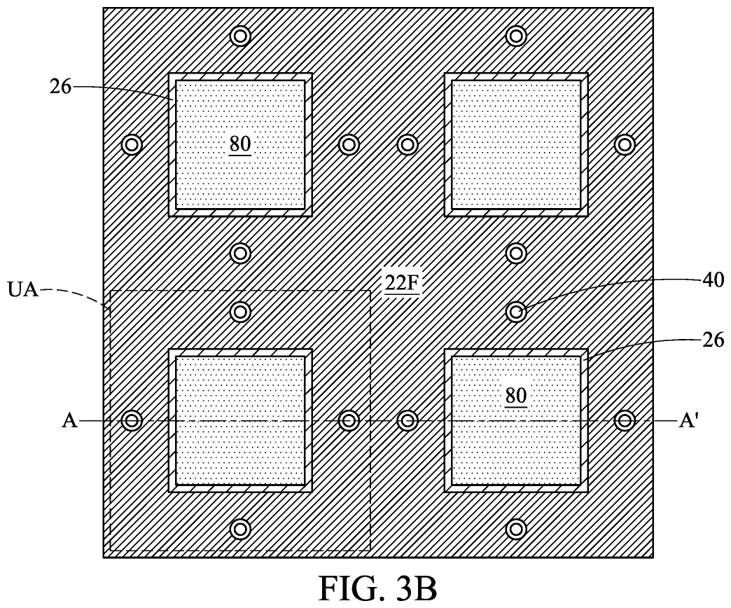

Referring to FIGS. 3A and 3B, an array of semiconductor packages 80 may be placed within an array of shuttle openings 27. Each semiconductor package 80 may be placed within the respective shuttle opening 27 on a top surface of a respective one of the conductive plates 26 using a pick-and-placement tool. Generally, the semiconductor packages 80 may comprise any type semiconductor packages known in the art. For example, the semiconductor packages 80 may comprise a single semiconductor die, a fan-in semiconductor die, a fan-out semiconductor die, a composite die including at least one semiconductor die and an interposer, a composite die including a vertical stack of at least two semiconductor dies, a chip-on-wafer-on-substrate package, or any other type of semiconductor package. In one embodiment, each semiconductor package 80 may comprise an array of solder material portions 88.

According to an aspect of the present disclosure, a second lateral gap LG2 is present between each sidewall of a semiconductor package 80 and a respective most proximal sidewall of the second lower shuttle structural element (such as the top shuttle plate 22T). According to an aspect of the present disclosure, the second lateral gap LG2 is designed to be at a positive value at the highest operating temperature of the lower shuttle assembly 20. In other words, even in embodiments in which the various components of the lower shuttle assembly 20 thermally expand to their respective maximum volume at the highest operating temperature of the lower shuttle assembly 20, the value for the second lateral gap LG2 remains positive, and the semiconductor packages 80 do not make physical contact with the combination of the top shuttle plate 22T. In one embodiment, the second lateral gap LG2 may be in a range from 300 microns to 5 mm, such as from 500 microns to 3 mm, although lesser and greater dimensions may also be used for the second lateral gap LG2.

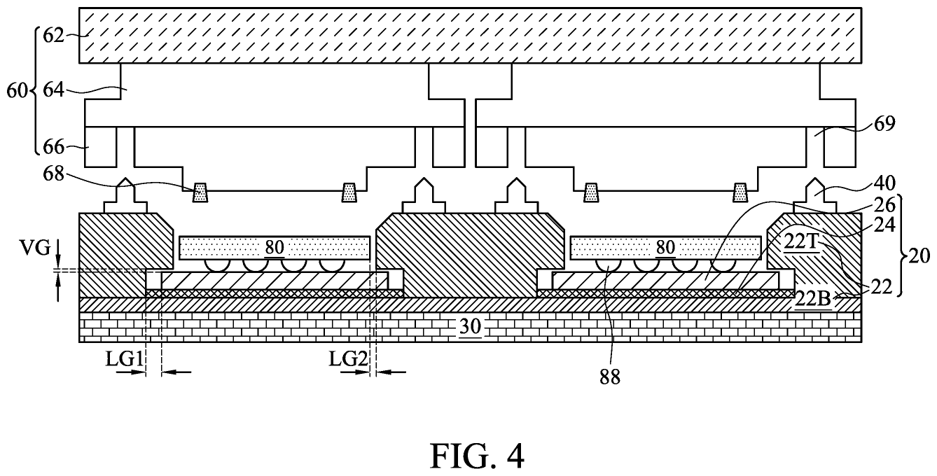

Referring to FIG. 4, an upper shuttle assembly 60 may be positioned over the lower shuttle assembly 20. The upper shuttle assembly 60 comprises a carrier substrate 62 and an array of package clamps (64, 66) attached to a bottom surface of the carrier substrate 62. In one embodiment, each package clamp (64, 66) may comprise a combination of a lower clamp portion 64 and an upper clamp portion 66. At least one fastener element 68 configured to fasten a respective underlying semiconductor package 80 may be provided at the bottom of each package clamp (64, 66). In an illustrative example, the at least one fastener element 68 may comprise at least one vacuum suction terminal connected to a vacuum pump (not illustrated) through the package clamp (64, 66). For example, vacuum tubes (not illustrated) may be provided within the package clamps (64, 66) and in, on, or above, the carrier substrate 62.

The array of package clamps (64, 66) may be arranged in a mirror image pattern of the pattern of the shuttle openings 27. The carrier substrate 62 provides structural support to the array of package clamps (64, 66). The upper shuttle assembly 60 is configured to mate with the lower shuttle assembly 20 such that the lower shuttle assembly 20 is secure against lateral movement relative to the upper shuttle assembly 60 upon mating of the lower shuttle assembly 20 with the upper shuttle assembly 60. For example, in embodiments in which the lower shuttle assembly 20 comprises an array of protrusions 40, the array of package clamps (64, 66) may comprise an array of cavities 69 or an array of vertical recesses configured to mate with the array of protrusions 40. The pattern of the array of cavities 69 or the array of vertical recesses may be a mirror image pattern of the pattern of the array of protrusions 40.

Generally, an array of fastener elements 68 may be provided to provide secure holding the semiconductor packages 80. Each package clamp (64,66) may be adjustable to accommodate different package sizes and shapes for the semiconductor package 80. Generally, the package clamps (64,66) may be configured to hold multiple packages simultaneously.

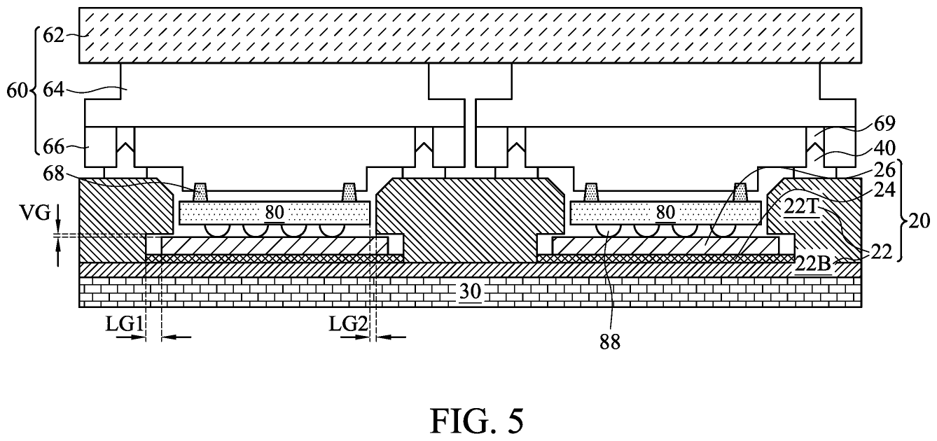

Referring to FIG. 5, the upper shuttle assembly 60 may be lowered onto the lower shuttle assembly 20 such that the array of protrusions 40 is aligned to the array of cavities 69. The array of fastener elements 68 may contact top surfaces of the semiconductor packages 80, and may fasten the semiconductor packages 80 to prevent lateral movement of the semiconductor packages 80. Once positionally fixed by the array of package clamps (64, 66), the semiconductor packages 80 are securely held to prevent any movement or structural damage during subsequent transportation and/or processing steps. The array of package clamps (64, 66) and the array of fastener elements 68 may be designed to exert just enough pressure to hold the semiconductor packages 80 without causing any damage to the semiconductor packages 80. In some embodiments, the array of fastener elements 68 may comprise an array of vacuum suction terminals, to which vacuum suction is applied during operation.

Generally, the upper shuttle assembly 60 comprises an array of fastener elements 68 that is pressed against top surfaces of the array of semiconductor packages 80 upon disposing the upper shuttle assembly 60 on the lower shuttle assembly 20. In one embodiment, an array of protrusions is provided on one of the array of package clamps (64, 66) and the lower shuttle assembly 20, and an array of cavities 69 or an array of recesses is provided on another of the array of package clamps (64, 66) and the lower shuttle assembly 20. The array of protrusions mates within the array of cavities 69 or with the array of recesses upon disposing the upper shuttle assembly 60 on the lower shuttle assembly 20.

The combination of the heater element 30, the lower shuttle assembly 20, and the upper shuttle assembly 60 constitutes a package shuttle (30, 20, 60). After the semiconductor packages 80 are securely held by the package shuttle (30, 20, 60), the semiconductor packages 80 and the package shuttle (30, 20, 60) may be transported from one location to another within a semiconductor manufacturing facility. In other words, the array of semiconductor packages 80 may be transported while the array of semiconductor packages 80 is contained within a combination of the lower shuttle assembly 20 and the upper shuttle assembly 60. The package shuttle (30, 20, 60) may be transported to and from different processing stations, such as assembly stations, testing stations, and/or inspection stations.

In one embodiment, the package shuttle (30, 20, 60) comprises a heater element 30 attached to a bottom surface of the first lower shuttle structural element (such as the bottom shuttle plate 22B). In this embodiment, the semiconductor packages 80 may be heated to an elevated temperature by generating heat from the heater element 30 after disposing the array of semiconductor packages 80 in the array of shuttle openings 27 prior to, during, and/or after transport of the semiconductor packages 80. In one embodiment, the second lower shuttle structural element (such as the top shuttle plate 22T) comprises a material having a lower thermal conductivity than the array of conductive plates 26. In this embodiment, thermal expansion of the second lower shuttle structural element may be reduced, and reduction of the dimension of the second lateral gap LG2 due to thermal expansion of the second lower shuttle structural element is reduced. This feature may be advantageously used to reduce the likelihood of contact between the semiconductor packages 80 and the second lower shuttle structural element during subsequent lifting of the semiconductor packages 80 out of the volumes of the shuttle openings 27. In one embodiment, the semiconductor packages 80 may be at a higher temperature than the average temperature of the at least one second lower shuttle structural element (such as the top shuttle plate 22T) upon heating the semiconductor packages 80.

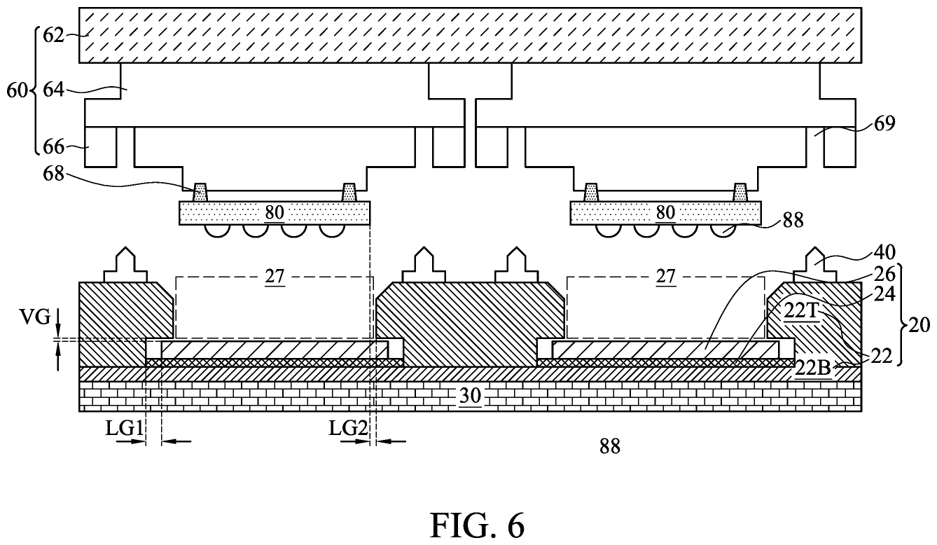

Referring to FIG. 6, the array of semiconductor packages 80 may be lifted out of the volumes of the shuttle openings 27 using the upper shuttle assembly 60. Subsequently, various processing steps may be performed on the semiconductor packages 80 while being securely held in the package clamps (64, 66) through the array of fastener elements 68. Exemplary processing steps include, but are not limited to, soldering steps, wire bonding steps, encapsulation steps, and electrical testing steps. Further, various quality control measures may be implemented to ensure that the semiconductor packages 80 meet the desired specifications. Such quality control measures may include visual inspection, functional testing, and other forms of testing. Once the semiconductor packages 80 undergo all necessary processing and quality control steps, the semiconductor packages 80 may be released from the package clamps (64, 66) for further handling or packaging.

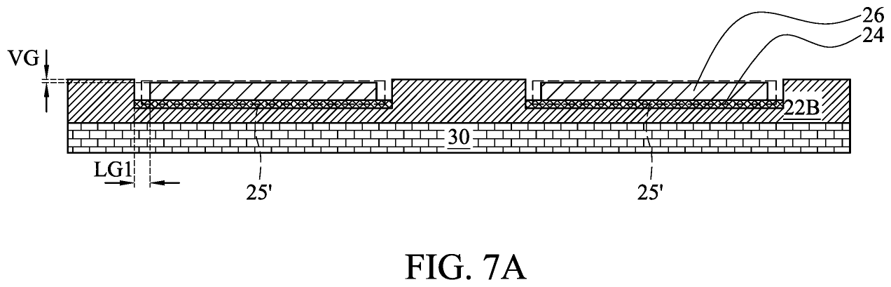

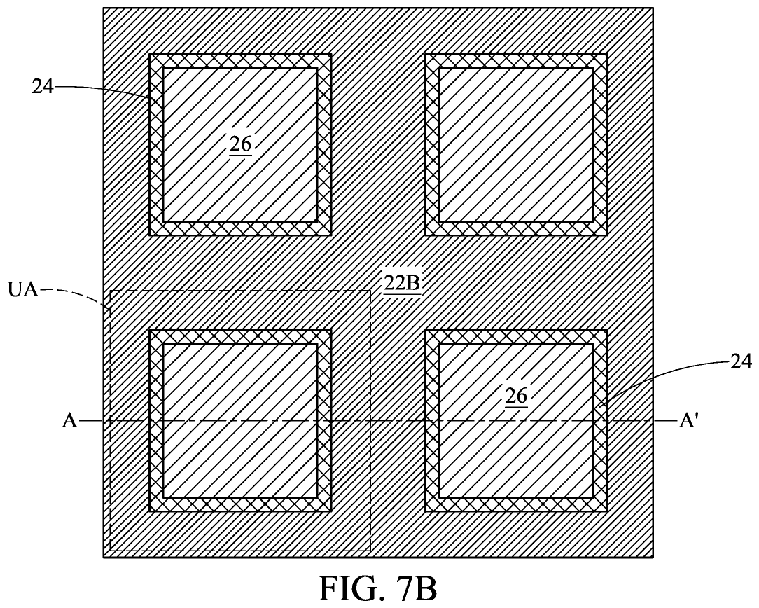

Referring to FIGS. 7A and 7B, a second embodiment structure may be derived from the first embodiment structure by modifying the bottom shuttle plate 22B. Specifically, the bottom shuttle plate 22B in the second embodiment structure has a height that equals the vertical distance between the heater element 30 and the bottom peripheries of the shuttle openings 27 described with reference to the first embodiment structure. According to an aspect of the present disclosure, the bottom shuttle plate 22B includes an array of recess cavities 25′ therein. In one embodiment, the array of recess cavities 25′ in the bottom shuttle plate 22B may have the same shapes and sizes as the array of cavities 25 described with reference to the first embodiment structure. The depth of each recess cavity 25′ may be greater than the sum of the thickness of a thermal interface material plate 24 and the thickness of a conductive plate 26. In one embodiment, the size of each recess cavity 25′ in a plan view may be the same as the size of a respective thermal interface material plate 24. In this embodiment, the entirety of the bottom surfaces of the array of recess cavities 25′ in the bottom shuttle plate 22B may be covered with the array of thermal interface material plates 24 upon formation of the array of thermal interface material plates 24. An array of conductive plate 26 may be formed on the top surfaces of the array of thermal interface material plates 24.

The top surfaces of the array of conductive plates 26 may be vertically recessed relative to the topmost surface of the bottom shuttle plate 22B by the vertical gap VG. The vertical gap VG may be in a range from 10 microns to 300 microns, such as from 20 microns to 200 microns, although lesser and greater values may also be used for the vertical gap VG (as measured at room temperature). Each conductive plate 26 within the array of conductive plates 26 is laterally spaced from the first lower shuttle structural element (such as the bottom shuttle plate 22B) by a lateral gap (such as a first lateral gap LG1). According to an aspect of the present disclosure, the first lateral gap LG1 is designed to be at a positive value at the highest operating temperature of a lower shuttle assembly. In other words, even in embodiments in which the various components of the lower shuttle assembly thermally expand to their respective maximum volume at the highest operating temperature of the lower shuttle assembly, the value for the first lateral gap LG1 remains positive, and the conductive plates 26 do not make physical contact with the bottom shuttle plate 22B.

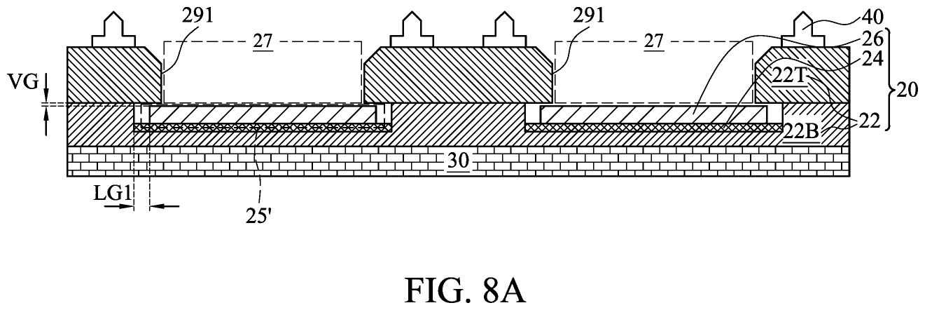

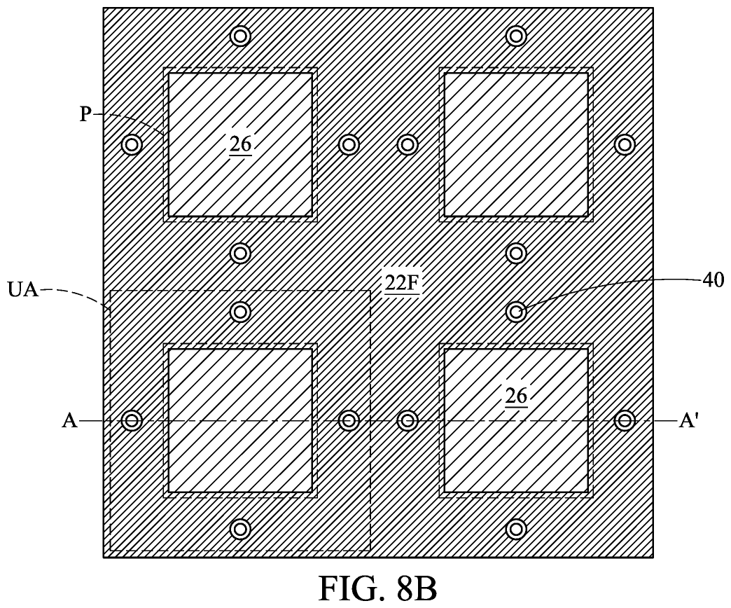

Referring to FIGS. 8A and 8B, a second lower shuttle structural element of the second embodiment structure is derived from the second lower shuttle structural element of the first embodiment structure by removing the portions of the second lower shuttle structural element of the first embodiment structure that underlie a horizontal plane including the bottom peripheries of the array of shuttle openings 27. In one embodiment, the second lower shuttle structural element of the second embodiment structure comprises a perforated plate (such as a top shuttle plate 22T) including the array of shuttle openings 27 therethrough. Each shuttle opening 27 within the array of shuttle openings 27 overlies a respective recess cavity 25′ within the array of recess cavities 25′, and has a lesser area than the respective recess cavity 25′.

The second lower shuttle structural element (comprising the top shuttle plate 22T) may be configured to mate with the top surface of the first lower shuttle structural element (comprising the bottom shuttle plate 22B) by contacting a grid-shaped physically-exposed surface segment of the top surface of the first lower shuttle structural element that is not covered by the array of thermal interface material plates 24. For example, the top shuttle plate 22T may be attached to the bottom shuttle plate 22B by using a combination of through-holes (not illustrated) that extend through the top shuttle plate 22T and the bottom shuttle plate 22B and fixture elements (such as bolts, nuts, screws, clips, etc.) that pass through the through-holes. Alternatively or additionally, an adhesive layer (not shown) may be used between the top shuttle plate 22T and the bottom shuttle plate 22B to bond the top shuttle plate 22T and the bottom shuttle plate 22B. The combination of the first lower shuttle structural element (which may be comprise the bottom shuttle plate 22B) and the second lower shuttle structural element (which may be comprise the top shuttle plate 22T) constitutes a shuttle plate assembly 22.

Upon assembly of the top shuttle plate 22T with the bottom shuttle plate 22B, a lower shuttle assembly 20 is formed. The lower shuttle assembly 20 comprises a first lower shuttle structural element (which may be comprise a bottom shuttle plate 22B), an array of thermal interface material plates 24 located over the first lower shuttle structural element, an array of conductive plates 26 located over the array of thermal interface material plates 24, and a second lower shuttle structural element (comprising a top shuttle plate 22T) including an array of shuttle openings 27 therethrough. The array of shuttle openings 27 overlies the array of conductive plates 26, and is configured to accommodate an array of semiconductor packages therein.

In one embodiment, the bottom shuttle plate 22B has a perforated top surface located above a horizontal plane including top surfaces of the array of conductive plates 26. In one embodiment, the lower shuttle assembly 20 comprises an array of recess cavities 25′ underneath the array of shuttle openings 27 such that each recess cavity 25′ selected from the array of recess cavities 25′ underlies, and has a greater lateral extent than, a respective shuttle opening 27 selected from the array of shuttle openings 27. In one embodiment, each shuttle opening 27 within the array of shuttle openings 27 is located inside an area of a periphery of a respective one of the conductive plates 26 in a plan view.

Generally, each conductive plate 26 within the array of conductive plates 26 is laterally spaced from a combination of the first lower shuttle structural element and the second lower shuttle structural element (such as a combination of the bottom shuttle plate 22B and the top shuttle plate 22T) by a lateral gap (such as a first lateral gap LG1). According to an aspect of the present disclosure, the first lateral gap LG1 is designed to be at a positive value at the highest operating temperature of the lower shuttle assembly 20. In other words, even in embodiments in which the various components of the lower shuttle assembly 20 thermally expand to their respective maximum volume at the highest operating temperature of the lower shuttle assembly 20, the value for the first lateral gap LG1 remains positive, and the conductive plates 26 do not make physical contact with the combination of the bottom shuttle plate 22B and the top shuttle plate 22T.

In one embodiment, the array of shuttle openings 27 comprises an array of first sidewalls 291 of the second lower shuttle structural element (such as the top shuttle plate 22T). In one embodiment, each first sidewall 291 may have a tapered upper sidewall segment and a vertical lower sidewall segment. The bottom peripheries of the first sidewalls 291 of the second lower shuttle structural element may be located above a horizontal plane including top surfaces of the array of conductive plates 26. In one embodiment, each conductive plate 26 within the array of conductive plates 26 is vertically spaced from a respective overhanging portion of the at least one second lower shuttle structural element (such as the top shuttle plate 22T) by a vertical gap VG. The vertical gap VG may be in a range from 10 microns to 300 microns, such as from 20 microns to 200 microns, although lesser and greater values may also be used for the vertical gap VG (as measured at room temperature).

In one embodiment, the periphery of the cavity 25 in each unit area UA may be laterally offset outward relative to the periphery of the overlying shuttle opening 27 by a lateral offset distance which is greater than the first lateral gap LG1. Thus, each conductive plate 26 may comprise a respective peripheral region having an areal overlap with a respective overhanging portion of the second lower shuttle structural element (such as the top shuttle plate 22T) in a plan view. In one embodiment, the top shuttle plate 22T includes stepped openings therethrough.

According to an aspect of the present disclosure, a top surface of the second lower shuttle structural element (such as the top shuttle plate 22T) may comprise an array of topographical features that may be used to induce self-alignment during mating of the lower shuttle assembly 20 with an upper shuttle assembly to be subsequently used. The topographical features may comprise an array of protrusions 40 or an array of cavities configured to receive a mating array of protrusions. In the illustrated example, the topographical features on the top surface of the top shuttle plate 22T comprise an array of protrusions 40. In one embodiment, the array of protrusions 40 may be arranged as a periodic array of protrusions 40 having the same periodicity as the array of shuttle openings 27. The array of topographical features may comprise geometrical features that are conductive to self-alignment between the top shuttle plate 22T and upper shuttle assembly to be subsequently used. If an array of protrusions 40 is used, the protrusions 40 may comprise a conical tip that may be advantageously used to induce lateral sliding between the top shuttle plate 22T and the upper shuttle assembly during a subsequent alignment process.

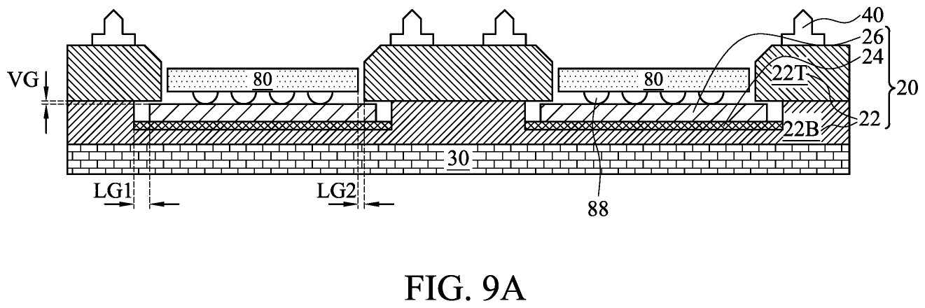

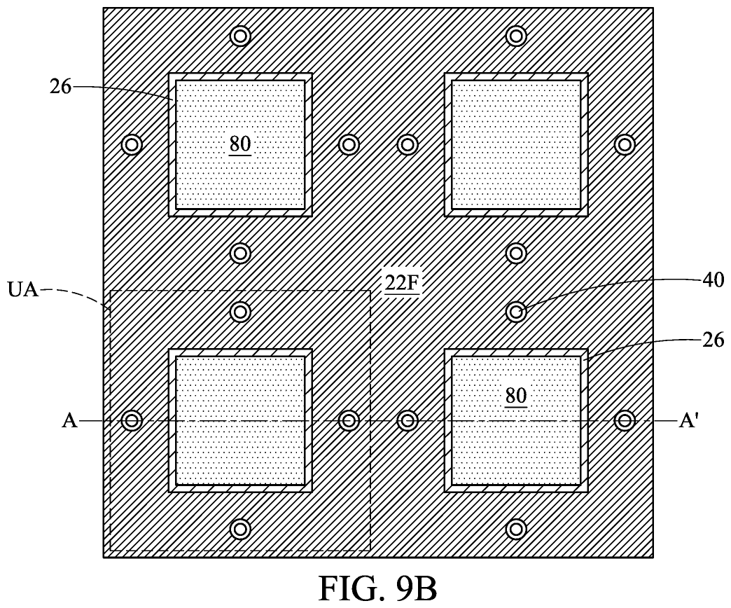

Referring to FIGS. 9A and 9B, an array of semiconductor packages 80 may be disposed within an array of shuttle openings 27 by performing the processing steps described with reference to FIGS. 3A and 3B.

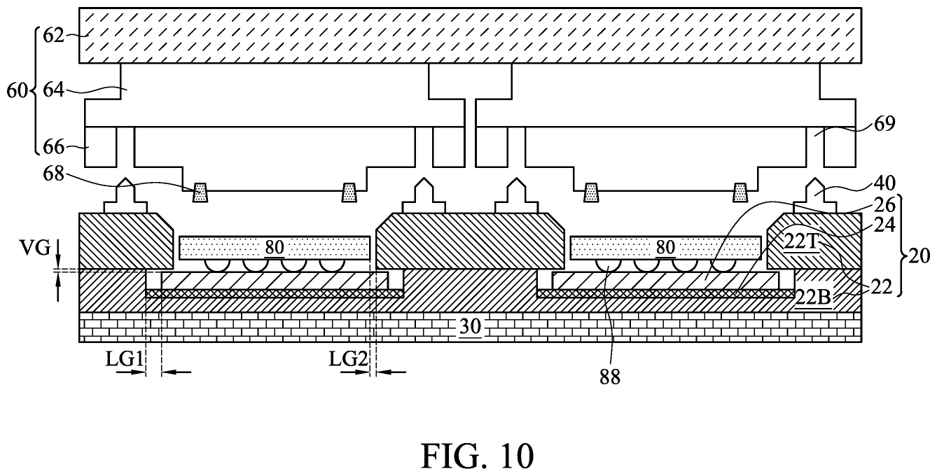

Referring to FIG. 10, an upper shuttle assembly 60 may be positioned over the lower shuttle assembly 20 as described with reference to FIG. 4.

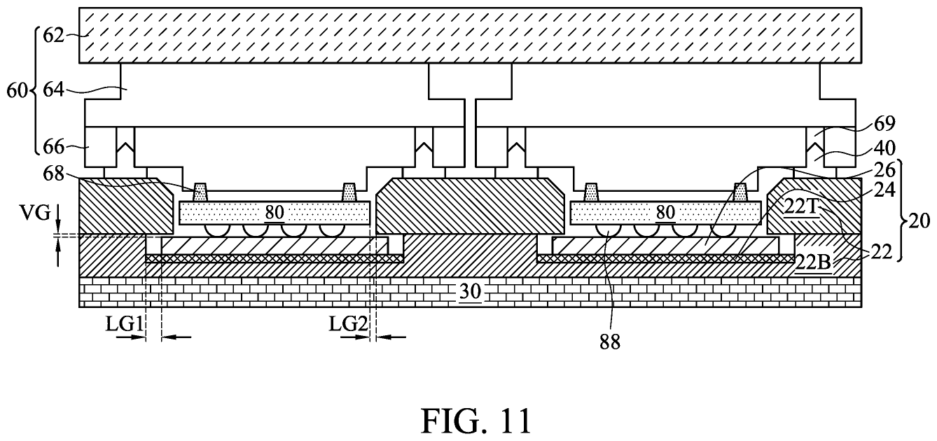

Referring to FIG. 11, the upper shuttle assembly 60 may be disposed on the lower shuttle assembly 20 as described with reference to FIG. 5. The array of semiconductor packages 80 may be positionally secured relative to the package shuttle (30, 20, 60), and may be transported with optional heating of the semiconductor packages 80.

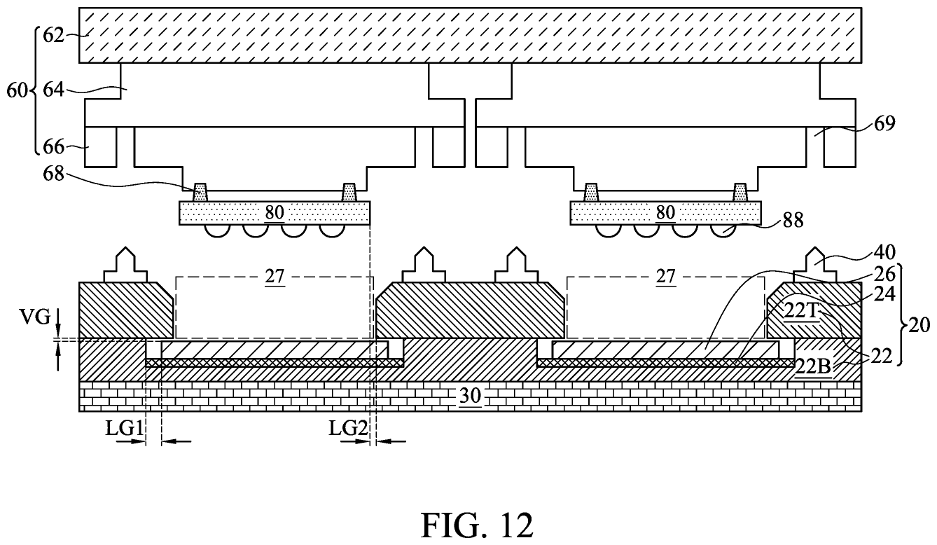

Referring to FIG. 12, the various processing steps described with reference to FIG. 6 may be performed. The semiconductor packages 80 may be lifted out of the shuttle openings 27.

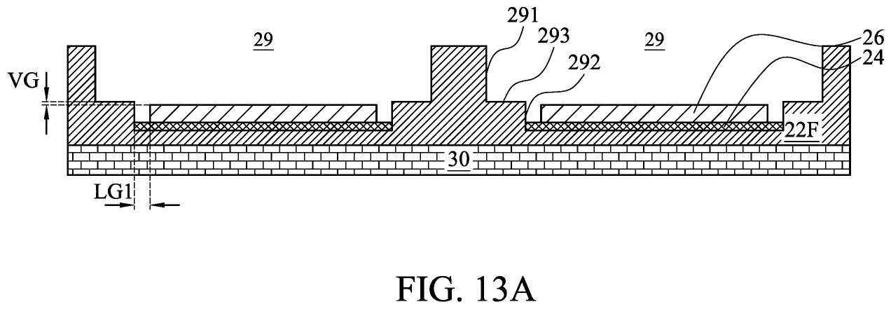

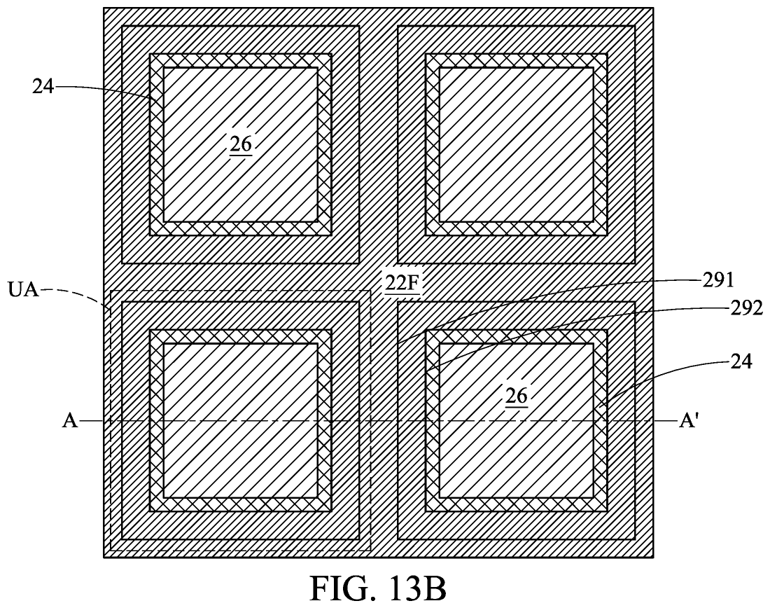

Referring to FIGS. 13A and 13B, a third embodiment structure may be derived from the second embodiment structure by modifying the bottom shuttle plate 22B into a shuttle frame 22F having a greater height. In one embodiment, the shuttle frame 22F in the third embodiment structure may have a height that equals the vertical distance between the heater element 30 in the second embodiment structure and the horizontal plane including the top surface of the second upper shuttle structural element (such as the top shuttle plate 22T) in the second embodiment structure.

In the third embodiment structure, the first lower shuttle structural element comprises a frame (such as a shuttle frame 22F) including a two-dimensional array of stepped recess cavities 29 therein. Each stepped recess cavity 29 within the array of stepped recess cavities 29 has a greater lateral dimension in an upper portion than in a lower portion. Each stepped recess cavity 29 comprises first sidewalls 291 located in an upper portion, second sidewalls 292 located in a lower portion, and a horizontal surface 293 connecting a bottom periphery of the first sidewalls 291 and a top periphery of the second sidewalls 292. Each volume that is laterally surrounded by a set of second sidewalls may be the same as the volume of a cavity 25 described with reference to the first embodiment structure, and/or the volume of a recess cavity 25′ described with reference to the second embodiment structure.

An array of thermal interface material plates 24 and an array of conductive plates 26 may be formed in the lower portions of the array of stepped recess cavities 29. The top surfaces of the array of conductive plates 26 may be vertically recessed relative to the horizontal plane including the horizontal surfaces 293 of the array of stepped recess cavity 29 by a vertical gap VG. The vertical gap VG may be in a range from 10 microns to 300 microns, such as from 20 microns to 200 microns, although lesser and greater values may also be used for the vertical gap VG (as measured at room temperature). Each conductive plate 26 within the array of conductive plates 26 is laterally spaced from a most proximal one to the second sidewalls 292 of the stepped recess cavities 29 by a lateral gap (such as a first lateral gap LG1). According to an aspect of the present disclosure, the first lateral gap LG1 is designed to be at a positive value at the highest operating temperature of a lower shuttle assembly. In other words, even in embodiments in which the various components of the lower shuttle assembly thermally expand to their respective maximum volume at the highest operating temperature of the lower shuttle assembly, the value for the first lateral gap LG1 remains positive, and the conductive plates 26 do not make physical contact with the shuttle frame 22F.

In one embodiment, each horizontal surface 293 of the stepped recess cavities 29 may have a frame shape, such as a rectangular frame shape. In one embodiment, the width of each segment of the rectangular frame shape of a horizontal surface 293 of a stepped recess cavity 29 may be in a range from 1 mm to 30 mm, such as from 2 mm to 15 mm, although lesser and greater widths may also be used. The height of each first sidewall 291 may be greater than the height of semiconductor packages to be subsequently used, and may be in a range from 1 mm to 5 mm, although lesser and greater heights may also be used.

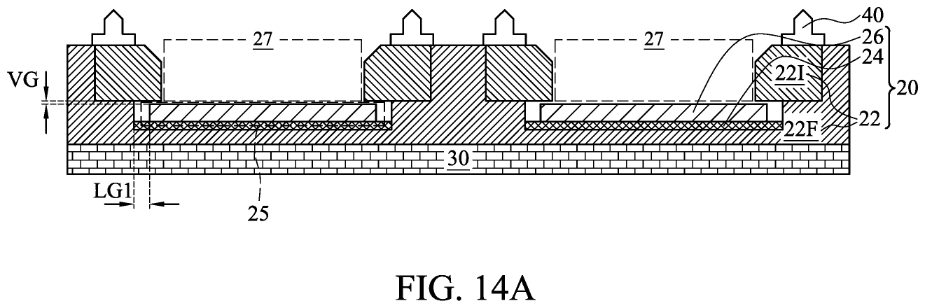

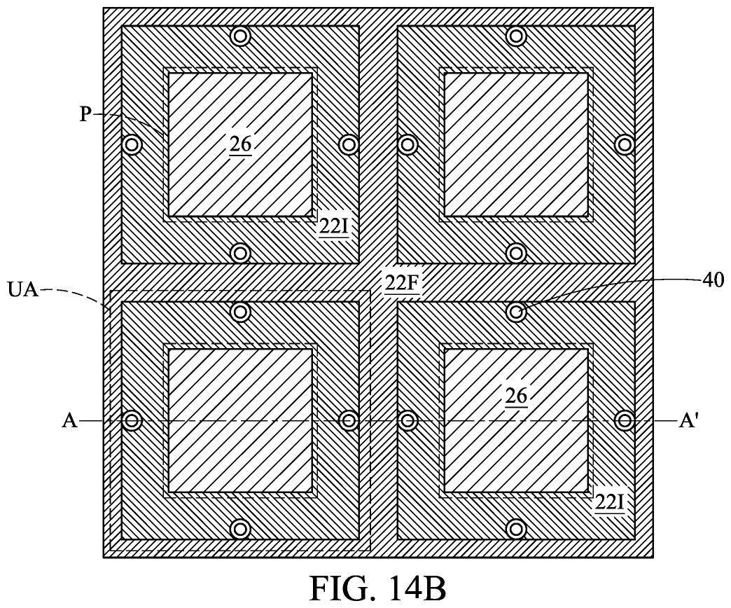

Referring to FIGS. 14A and 14B, a plurality of second lower shuttle structural elements may be attached to the first lower shuttle structural element (which is comprise a shuttle frame 22F). In one embodiment, a plurality of perforated inserts 22I may be used as the plurality of second lower shuttle structural elements. In one embodiment, the plurality of perforated inserts 22I may be inserted into the upper portions of the stepped recess cavities 29 by sliding downward into a respective final position. Each perforated insert 22I may be configured to fit into the upper portion of a respective one of the stepped recess cavities 29, and comprises an opening therethrough which is a shuttle opening 27. A two-dimensional array of perforated inserts 22I may be inserted into the two-dimensional array of stepped recess cavities 29, and a two-dimensional array of shuttle openings 27 may be provided within the two-dimensional array of perforated inserts 22I.

In the third embodiment structure, an array of perforated inserts 22I may be disposed within the upper portions of the array of stepped recess cavities 29 after formation of the array of thermal interface material plates 24 and the array of conductive plates 26. Each perforated insert 22I within the array of perforated inserts 22I comprises a respective shuttle opening 27 within the array of shuttle openings 27. The combination of the first lower shuttle structural element (comprising the shuttle frame 22F) and a plurality of second lower shuttle structural elements (comprising an array of perforated inserts 22I) constitutes a shuttle plate assembly 22.

Generally, the shuttle plate assemblies 22 of the various embodiment structures may have a same total volume and a same overall shape. However, the distribution of volumes between a first lower shuttle structural element and at least one second lower shuttle structural element may be different from the various embodiment structures of the present disclosure.

In the third embodiment structure, the shuttle plate assembly 22 comprises an array of topographical features that may be used to induce self-alignment during mating of the lower shuttle assembly 20 with an upper shuttle assembly to be subsequently used. The topographical features may comprise an array of protrusions 40 or an array of cavities 25 configured to receive a mating array of protrusions 40. In the illustrated example, the topographical features on the top surfaces of the perforated inserts 22I comprise an array of protrusions 40. While the present disclosure is described using an embodiment in which the array of protrusions 40 is provided on the array of perforated inserts 22I, embodiments are expressly contemplated herein in which the array of topological features is provided on a top surface of the shuttle frame 22F. In one embodiment, the array of protrusions 40 may be arranged as a periodic array of protrusions 40 having the same periodicity as the array of shuttle openings 27. The array of topographical features may comprise geometrical features that are conductive to self-alignment between the top shuttle plate 22T and upper shuttle assembly to be subsequently used. In embodiments in which an array of protrusions 40 is used, the protrusions 40 may comprise a conical tip that may be advantageously used to induce lateral sliding between the top shuttle plate 22T and the upper shuttle assembly during a subsequent alignment process.

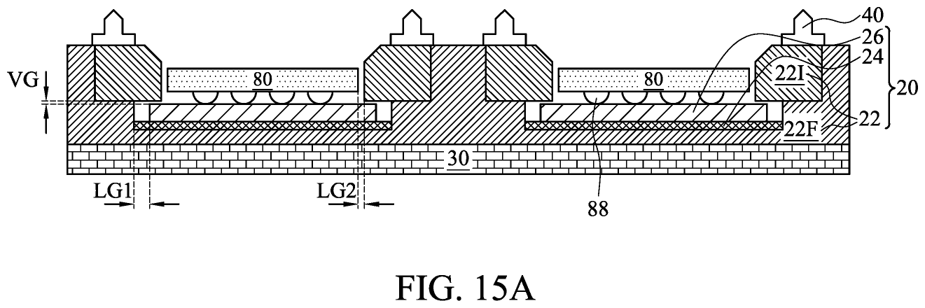

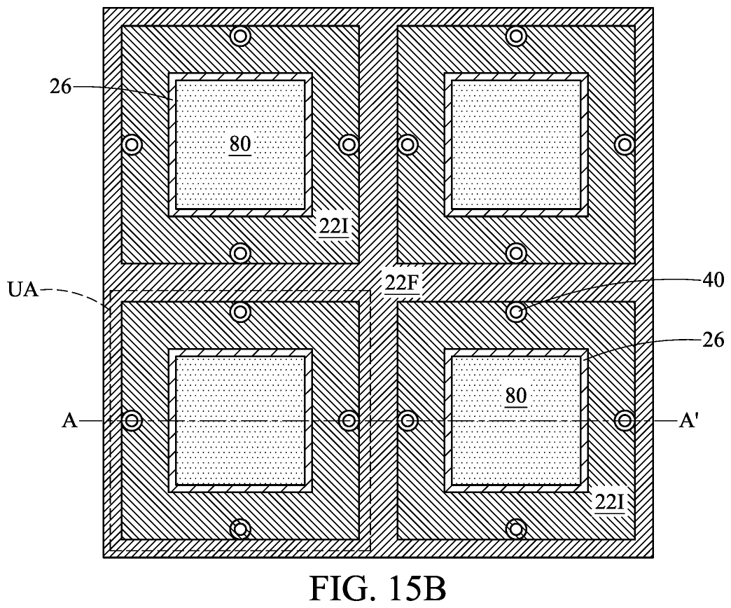

Referring to FIGS. 15A and 15B, an array of semiconductor packages 80 may be disposed within an array of shuttle openings 27 by performing the processing steps described with reference to FIGS. 3A and 3B.

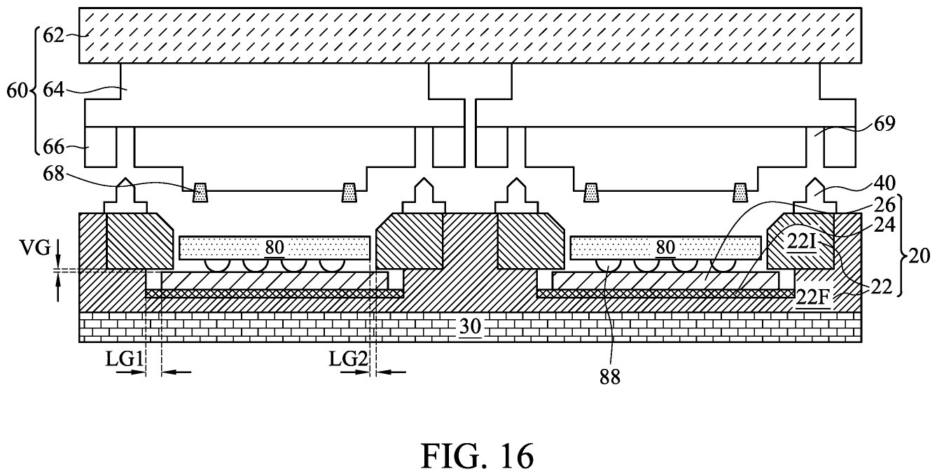

Referring to FIG. 16, an upper shuttle assembly 60 may be positioned over the lower shuttle assembly 20 as described with reference to FIG. 4.

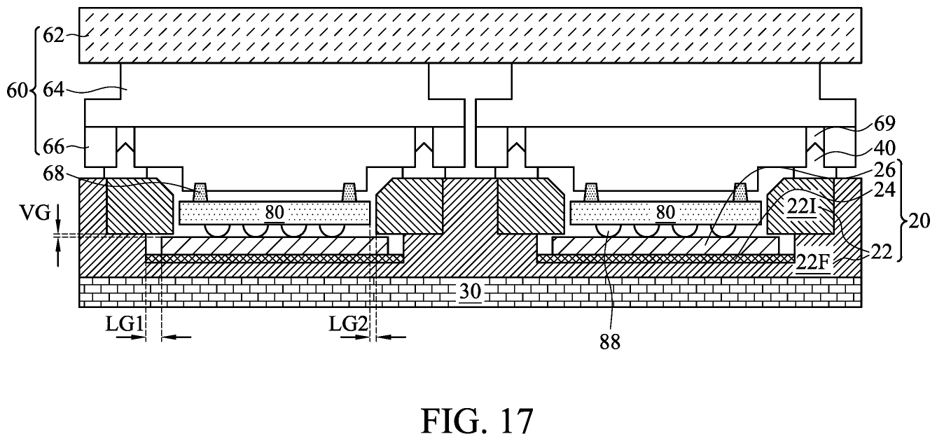

Referring to FIG. 17, the upper shuttle assembly 60 may be disposed on the lower shuttle assembly 20 as described with reference to FIG. 5. The array of semiconductor packages 80 may be positionally secured relative to the package shuttle (30, 20, 60), and may be transported with optional heating of the semiconductor packages 80.

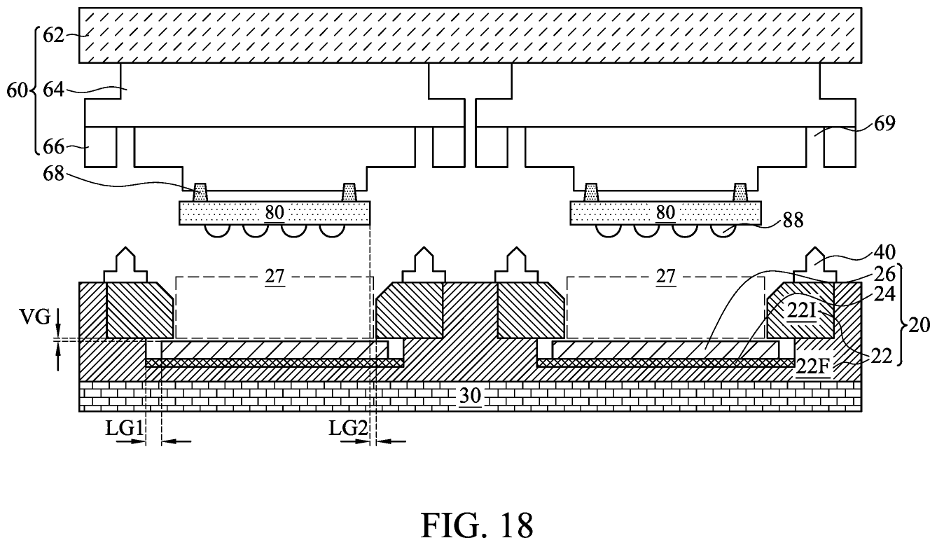

Referring to FIG. 18, the various processing steps described with reference to FIG. 6 may be performed. The semiconductor packages 80 may be lifted out of the shuttle openings 27.

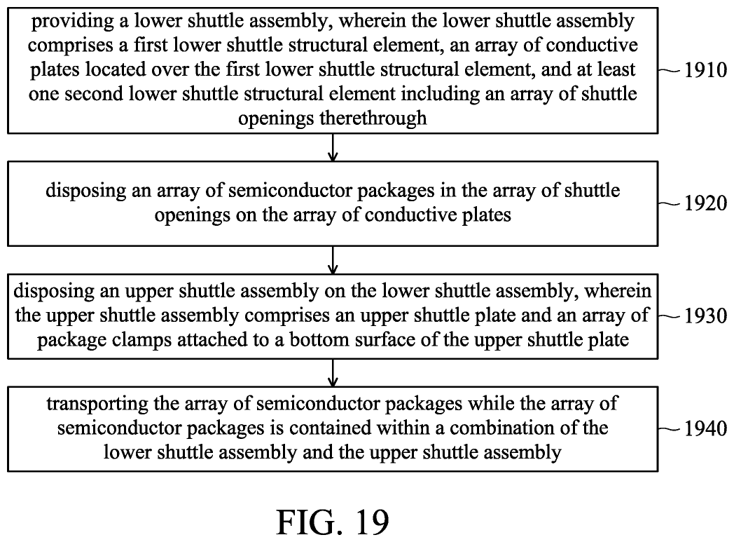

FIG. 19 is a flowchart that illustrates general processing steps for manufacturing a device structure according to an embodiment of the present disclosure.

Referring to step 1910 and FIGS. 1A-2D, 7A-8B, and 13A-14B, a lower shuttle assembly 20 is provided. The lower shuttle assembly 20 comprises a first lower shuttle structural element (22B, 22F), an array of conductive plates 26 located over the first lower shuttle structural element (22B, 22F), and at least one second lower shuttle structural element (22T, 22I) including an array of shuttle openings 27 therethrough.

Referring to step 1920 and FIGS. 3A, 3B, 9A, 9B, 15A, and 15B, an array of semiconductor packages 80 may be disposed in the array of shuttle openings 27 on the array of conductive plates 26.

Referring to step 1930 and FIGS. 4, 10, and 16, an upper shuttle assembly 60 may optionally be disposed on the lower shuttle assembly 20. The upper shuttle assembly 60 comprises a carrier substrate 62 and an array of package clamps (64, 66) attached to a bottom surface of the carrier substrate 62.

Referring to step 1940 and FIGS. 5, 6, 11, 12, 17, and 18, the array of semiconductor packages 80 may be transported while the array of semiconductor packages 80 is contained within a combination of the lower shuttle assembly 20 and the upper shuttle assembly 60.

Referring to all drawings and according to various embodiments of the present disclosure, a package shuttle (30, 20, 60) is provided. The package shuttle (30, 20, 60) comprises a lower shuttle assembly 20 comprising a first lower shuttle structural element (22B, 22F), an array of conductive plates 26 located over the first lower shuttle structural element (22B, 22F), and at least one second lower shuttle structural element (22T, 22I) including an array of shuttle openings 27 therethrough, wherein the array of shuttle openings 27 overlies the array of conductive plates 26 and is configured to accommodate an array of semiconductor packages 80 therein.

In one embodiment, each shuttle opening 27 within the array of shuttle openings 27 is located inside an area of a periphery of a respective one of the conductive plates 26 in a plan view. In one embodiment, the lower shuttle assembly 20 comprises an array of cavities 25 underneath the array of shuttle openings 27 such that each cavity 25 selected from the array of cavities 25 underlies, and has a greater lateral extent than, a respective shuttle opening 27 selected from the array of shuttle openings 27. In one embodiment, the array of shuttle openings 27 comprises an array of first sidewalls 291 of the at least one second lower shuttle structural element (22T, 22I); and bottom peripheries of the first sidewalls 291 of the at least one second lower shuttle structural element (22T, 22I) are located above a horizontal plane including top surfaces of the array of conductive plates 26.

In one embodiment, the package shuttle (30, 20, 60) comprises an array of thermal interface material plates 24 in contact with the first lower shuttle structural element (22B, 22F), wherein each thermal interface material plate 24 within the array of thermal interface material plates 24 is in contact with a bottom surface of a respective conductive plate 26 within the array of conductive plates 26.

In one embodiment, each conductive plate 26 within the array of conductive plates 26 is laterally spaced from a combination of the first lower shuttle structural element and the at least one second lower shuttle structural element by a lateral gap (such as a first lateral gap LG1). In one embodiment, each conductive plate 26 within the array of conductive plates 26 is vertically spaced from a respective overhanging portion of the at least one second lower shuttle structural element (22T, 22I) by a vertical gap VG.

In one embodiment, the first lower shuttle structural element comprises an unperforated plate (such as a bottom shuttle plate 22B) having a planar top surface located under a horizontal plane including bottom surfaces of the array of conductive plates 26; and the at least one second lower shuttle structural element comprises a perforated plate (such as a top shuttle plate 22T) including stepped openings therethrough, wherein each of the stepped openings comprises a respective shuttle opening 27 within the array of shuttle openings 27 and further comprises a respective plate-level opening (such as a cavity 25) within an array of plate-level openings (such as the cavities 25), the respective plate-level opening (such as a cavity 25) having a greater area than the respective shuttle opening 27, for example, as illustrated in FIGS. 1A-6.

In one embodiment, the first lower shuttle structural element comprises an unperforated plate (such as a bottom shuttle plate 22B) including an array of recess cavities 25′, wherein the array of conductive plates 26 is located within the array of recess cavities 25′; and the at least one second lower shuttle structural element comprises a perforated plate (such as a top shuttle plate 22T) including the array of shuttle openings 27 therethrough, wherein each shuttle opening 27 within the array of shuttle openings 27 overlies a respective recess cavity 25′ within the array of recess cavities 25′ and has a lesser area than the respective recess cavity 25′, for example, as illustrated in FIGS. 7A-12.

In one embodiment, the first lower shuttle structural element 22B comprises a frame (such as a shuttle frame 22F) including a two-dimensional array of stepped recess cavities 29 therein, wherein each stepped recess cavity 29 within the array of stepped recess cavities 29 has a greater lateral dimension in an upper portion than in a lower portion; and the at least one second lower shuttle structural element comprises an array of perforated inserts 22I that is located within the upper portions of the array of stepped recess cavities 29, wherein each perforated insert 22I within the array of perforated inserts 22I comprises a respective shuttle opening 27 within the array of shuttle openings 27, for example, as illustrated in FIGS. 13A-18.

In one embodiment, the package shuttle may further includes an upper shuttle assembly, wherein the upper shuttle assembly includes: a carrier substrate; and an array of package clamps attached to a bottom surface of the carrier substrate, wherein the array of package clamps is configured to mate with the lower shuttle assembly such that the lower shuttle assembly is secure against lateral movement relative to the upper shuttle assembly upon mating of the lower shuttle assembly with the upper shuttle assembly.

According to an aspect of the present disclosure, a structure comprising a package shuttle (30, 20, 60) is provided. The package shuttle (30, 20, 60) comprises: a lower shuttle assembly 20 comprising a first lower shuttle structural element (22B, 22F), an array of thermal interface material plates 24 located on the first lower shuttle structural element (22B, 22F), an array of conductive plates 26 located on the array of thermal interface material plates 24, and at least one second lower shuttle structural element (22T, 22I) including an array of shuttle openings 27 therethrough, wherein the array of shuttle openings 27 overlies the array of conductive plates 26 and is configured to accommodate an array of semiconductor packages 80 therein.

In one embodiment, the first lower shuttle structural element (22B, 22F) and the at least one second lower shuttle structural element (22T, 22I) have a respective thermal conductivity that is less than a thermal conductivity of the array of conductive plates 26. In one embodiment, the package shuttle (30, 20, 60) comprises a heater element 30 attached to a bottom surface of the first lower shuttle structural element (22B, 22F).

In one embodiment, the array of conductive plates 26 comprises a metallic material having a thermal conductivity that is greater than a thermal conductivity of a material of the array of thermal interface material plates 24 at least by a factor of 10. In one embodiment, the structure further comprises an array of semiconductor packages 80 located within the array of shuttle openings 27, wherein each semiconductor package 80 within the array of semiconductor packages 80 comprises a respective array of solder material portions 88 that contacts a top surface of a respective conductive plate 26 within the array of conductive plates 26.

Generally, thermal expansion of various components of a package shuttle may result in various deleterious effects that may result in damage or degradation of semiconductor packages 80 under transport. For example, topographical protrusions 40 (such as guide pins) and topographical recesses between a lower shuttle assembly and an upper shuttle assembly may be lodged against each other at a processing step at which the lower shuttle assembly and the upper shuttle assembly need to separate from each other. Such mechanical malfunction may result in unusual wear and tear on topographical protrusions and topographical recesses, and may compromise the integrity of vacuum suctions on the semiconductor packages 80 and may cause a fraction of the semiconductor packages 80 to drop during, or after, transport of the semiconductor packages 80 in the package shuttle. The various embodiments of the present disclosure reduces transmission of heat from the heater element 30 to the at least one second lower shuttle structural element (such as a top shuttle plate 22T or a plurality of perforated inserts 22I) and/or to the upper shuttle assembly while effectively transmitting heat from the heater element 30 to the semiconductor packages 80.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph of in different paragraphs, a Markush group including a listing of the two or more elements may be also impliedly disclosed in some embodiments. Whenever the auxiliary verb “may” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “may” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package shuttle comprising a lower shuttle assembly, wherein the lower shuttle assembly comprises:
a first lower shuttle structural element;
an array of conductive plates located over the first lower shuttle structural element; and
at least one second lower shuttle structural element including an array of shuttle openings therethrough, wherein the array of shuttle openings overlies the array of conductive plates and is configured to accommodate an array of semiconductor packages therein.

2. The package shuttle of claim 1, wherein each shuttle opening within the array of shuttle openings is located inside an area of a periphery of a respective one of the conductive plates in a plan view.

3. The package shuttle of claim 1, wherein the lower shuttle assembly comprises an array of cavities underneath the array of shuttle openings such that each cavity selected from the array of cavities underlies, and has a greater lateral extent than, a respective shuttle opening selected from the array of shuttle openings.

4. The package shuttle of claim 3, wherein:
the array of shuttle openings comprises an array of first sidewalls of the at least one second lower shuttle structural element; and
bottom peripheries of the first sidewalls of the at least one second lower shuttle structural element are located above a horizontal plane including top surfaces of the array of conductive plates.

5. The package shuttle of claim 1, further comprising an array of thermal interface material plates in contact with the first lower shuttle structural element, wherein each thermal interface material plate within the array of thermal interface material plates is in contact with a bottom surface of a respective conductive plate within the array of conductive plates.

6. The package shuttle of claim 1, wherein each conductive plate within the array of conductive plates is laterally spaced from a combination of the first lower shuttle structural element and the at least one second lower shuttle structural element by a lateral gap.

7. The package shuttle of claim 1, wherein each conductive plate within the array of conductive plates is vertically spaced from a respective overhanging portion of the at least one second lower shuttle structural element by a vertical gap.

8. The package shuttle of claim 1, wherein:
the first lower shuttle structural element comprises an unperforated plate having a planar top surface located under a horizontal plane including bottom surfaces of the array of conductive plates; and
the at least one second lower shuttle structural element comprises a perforated plate including stepped openings therethrough, wherein each of the stepped openings comprises a respective shuttle opening within the array of shuttle openings and further comprises a respective plate-level opening within an array of plate-level openings, the respective plate-level opening having a greater area than the respective shuttle opening.

9. The package shuttle of claim 1, wherein:
the first lower shuttle structural element comprises an unperforated plate including an array of recess cavities, wherein the array of conductive plates is located within the array of recess cavities; and
the at least one second lower shuttle structural element comprises a perforated plate including the array of shuttle openings therethrough, wherein each shuttle opening within the array of shuttle openings overlies a respective recess cavity within the array of recess cavities and has a lesser area than the respective recess cavity.

10. The package shuttle of claim 1, wherein:
the first lower shuttle structural element comprises a frame including a two-dimensional array of stepped recess cavities therein, wherein each stepped recess cavity within the array of stepped recess cavities has a greater lateral dimension in an upper portion than in a lower portion; and
the at least one second lower shuttle structural element comprises an array of perforated inserts that is located within the upper portions of the array of stepped recess cavities, wherein each perforated insert within the array of perforated inserts comprises a respective shuttle opening within the array of shuttle openings.

11. The package shuttle of claim 1, further comprising an upper shuttle assembly, wherein the upper shuttle assembly comprises:
a carrier substrate; and
an array of package clamps attached to a bottom surface of the carrier substrate, wherein the array of package clamps is configured to mate with the lower shuttle assembly such that the lower shuttle assembly is secure against lateral movement relative to the upper shuttle assembly upon mating of the lower shuttle assembly with the upper shuttle assembly.

12. A structure comprising a package shuttle, wherein the package shuttle comprises a lower shuttle assembly which comprises:
a first lower shuttle structural element;
an array of thermal interface material plates located on the first lower shuttle structural element;
an array of conductive plates located on the array of thermal interface material plates; and
at least one second lower shuttle structural element including an array of shuttle openings therethrough, wherein the array of shuttle openings overlies the array of conductive plates and is configured to accommodate an array of semiconductor packages therein.

13. The structure of claim 12, wherein the first lower shuttle structural element and the at least one second lower shuttle structural element have a respective thermal conductivity that is less than a thermal conductivity of the array of conductive plates.

14. The structure of claim 12, wherein the package shuttle comprises a heater element attached to a bottom surface of the first lower shuttle structural element.

15. The structure of claim 12, wherein the array of conductive plates comprises a metallic material having a thermal conductivity that is higher than a thermal conductivity of a material of the array of thermal interface material plates at least by a factor of 10.

16. A method of transporting semiconductor packages, the method comprising:
providing a lower shuttle assembly, wherein the lower shuttle assembly comprises:
a first lower shuttle structural element;
an array of conductive plates located over the first lower shuttle structural element; and
at least one second lower shuttle structural element including an array of shuttle openings therethrough;
disposing an array of semiconductor packages in the array of shuttle openings on the array of conductive plates; and
transporting the array of semiconductor packages while the array of semiconductor packages is contained within the lower shuttle assembly.

17. The method of claim 16, wherein:
an array of protrusions is provided on one of the array of package clamps and the lower shuttle assembly;
an array of cavities or an array of recesses is provided on another of the array of package clamps and the lower shuttle assembly; and
the array of protrusions mates within the array of cavities or with the array of recesses upon disposing the upper shuttle assembly on the lower shuttle assembly.

18. The method of claim 16, further comprising disposing an upper shuttle assembly on the lower shuttle assembly, wherein:
the upper shuttle assembly comprises a carrier substrate, an array of package clamps attached to a bottom surface of the carrier substrate, and an array of fastener elements that is pressed against top surfaces of the array of semiconductor packages upon disposing the upper shuttle assembly on the lower shuttle assembly; and
wherein the array of semiconductor packages is transported while the upper shuttle assembly is disposed on the lower shuttle assembly.

19. The method of claim 16, wherein:
a heater element is located on a bottom surface of the first lower shuttle structural element; and
the method comprises heating the semiconductor packages by generating heat from the heater element after disposing the array of semiconductor packages in the array of shuttle openings.

20. The method of claim 19, wherein:
wherein the at least one second lower shuttle structural element comprises a material having a lower thermal conductivity than the array of conductive plates; and
the semiconductor packages are at a higher temperature than an average temperature of the at least one second lower shuttle structural element upon heating the semiconductor packages.
